(19) United States
(12) Patent Application Publication
(10) Pub. No.: US 2024/0313503 A1
(43) Pub. Date: Sep. 19, 2024

(54) ELECTRO-ABSORPTION MODULATED LASERS WITH IDENTICAL-ACTIVE LAYER

(71) Applicant: ELECTRONICS AND TELECOMMUNICATIONS RESEARCH INSTITUTE, Daejeon (KR)

(72) Inventors: Namje KIM, Daejeon (KR); O-Kyun KWON, Daejeon (KR); Ho Sung KIM, Daejeon (KR); Miran PARK, Daejeon (KR); Seungchul LEE, Daejeon (KR)

(21) Appl. No.: 18/606,448

(22) Filed: Mar. 15, 2024

(30) Foreign Application Priority Data
Mar. 17, 2023 (KR) 10-2023-0035288

(51) Int. Cl. H01S 5/026; H01S 5/042; H01S 5/12

(52) U.S. Cl. CPC H01S 5/0265; H01S 5/04256; H01S 5/12

(57) ABSTRACT

Provided is an electro-absorption modulated lasers with identical-active layer. The lasers include a substrate having a passive waveguide region, an LD region on one side of the passive waveguide region, and an EAM region on the other side of the passive waveguide region, an active layer provided on the substrate and extending from the LD region to the EAM region, a grating layer provided on the active layer, a clad layer provided on the grating layer, and electrodes provided in the LD region and the EAM region of the clad layer.

### CROSS-REFERENCE TO RELATED APPLICATIONS

This U.S. non-provisional patent application claims priority under 35 U.S.C. § 119 of Korean Patent Application No. 10-2023-0035288, filed on Mar. 17, 2023, the entire contents of which are hereby incorporated by reference.

### BACKGROUND

The present disclosure relates to an electro-absorption modulated lasers, and more particularly to an electro-absorption modulated lasers with identical-active layer.

In general, an electroabsorption modulated laser (EML) is an optical element in which a distributed feedback laser diode (DFB LD) and an electroabsorption modulator (EAM) are integrated on a single substrate and has been used for long-distance optical communication. As the transmission rate of optical communication has increased to 25 Gbps or higher due to the introduction of 5G communication networks and the development of data centers, and a directly modulated laser (DML), which has been used in typical short-range communication, has become problematic due to distribution properties associated with high-speed modulation, so that the use of an EML, which has relatively excellent distribution properties, is increasing even in short-range high-speed communication. The increase in the use of an EML, which is expensive and has a relatively complex element structure, naturally results in a technical demand for simplification of an element composition and low cost. In addition, due to the increase in wireless communication volume, it is necessary to expand outdoor communication networks and increase the capacity thereof, such as fronthaul, and elements installed outdoors should not only have excellent high-temperature properties but also consume less power.

### SUMMARY

The present disclosure provides an electro-absorption modulated lasers with identical-active layer capable of acquiring linear extinction ratio (ER) properties.

An embodiment of the inventive concept provides an electro-absorption modulated lasers with identical-active layer. The lasers include a substrate having a passive waveguide region, an LD region on one side of the passive waveguide region, and an EAM region on another side of the passive waveguide region, an active layer provided on the substrate and extending from the LD region to the EAM region, a grating layer provided on the active layer, a clad layer provided on the grating layer, and electrodes provided in the LD region and the EAM region of the clad layer. Here, the active layer may have a first thickness in the passive waveguide region, a second thickness, which is greater than the first thickness, in the LD region, and a minimum variable thickness and a maximum variable thickness, which are greater than the first thickness and less than the second thickness, in the EAM region.

In an embodiment, the active layer having the maximum variable thickness may be provided adjacent to the passive waveguide region.

In an embodiment, the active layer having the minimum variable thickness may be provided adjacent to the passive waveguide region, and the minimum variable thickness may be the same as the first thickness.

In an embodiment, the lasers may further include a first SCH layer between the substrate and the active layer, and a second SCH sublayer between the active layer and the grating layer.

In an embodiment, the active layer may be curved between the passive waveguide region and the LD region, and may be curved between the passive waveguide region and the EAM region.

In an embodiment, the grating layer may extend from the LD region to the EAM region.

In an embodiment, the grading layer may be curved between the passive waveguide region and the LD region, and may be curved between the passive waveguide region and the EAM region.

In an embodiment, the active layer may be formed by a SAG method using a SAG mask pattern as a deposition mask.

In an embodiment, the SAG mask pattern may include a first opening having a first width in the passive waveguide region, a second opening having a second width, which is narrower than the first width, in the LD viewing region, and a third opening having a maximum variable width and a minimum variable width, which are narrower than the first width and wider than the second width, in the EAM region.

In an embodiment, the maximum variable width may be the same as the second width.

In an embodiment of the inventive concept, an element with identical-active layer includes a substrate having a passive waveguide region, an LD region on one side of the passive waveguide region, and an EAM region on another side of the passive waveguide region, an active layer provided on the substrate and thinner than the EAM region in the passive waveguide region and thicker than the EAM region in the LD region, a grating layer provided on the active layer, a clad layer provided on the grating layer, and electrodes provided in the LD region and the EAM region of the clad layer.

In an embodiment, the active layer may extend from the LD region to the EAM region.

In an embodiment, the active layer may be formed by a SAG method using a SAG mask pattern as a deposition mask.

In an embodiment, the SAG mask pattern may include a first opening having a first width in the passive waveguide region, a second opening having a second width in the LD region, and a third opening having a variable width in the EAM region.

In an embodiment, the variable width may be narrower than the first width and wider than the second width.

In an embodiment of the inventive concept, an element with identical-active layer includes a substrate having a passive waveguide region, a laser diode region on one side of the passive waveguide region, and a modulation region on another side of the passive waveguide region, an active layer provided on the substrate and extending from the laser diode region to the modulation region, a grating layer provided on the active layer, a clad layer provided on the grating layer, and electrodes provided in the laser diode region and the passive waveguide region of the clad layer. Here, the modulation region of the active layer may be thicker than the passive waveguide region and thinner than the laser diode region.

In an embodiment, the active layer may have a first thickness in the passive waveguide region, a second thickness, which is greater than the first thickness, in the laser diode region, and a third thickness, which is greater than the first thickness and less than the second thickness, in the modulation region.

In an embodiment, the third thickness may include a maximum variable thickness and a minimum variable thickness.

In an embodiment, the active layer having the maximum variable thickness may be provided adjacent to the passive waveguide region.

In an embodiment, the minimum variable thickness may be the same as the first thickness.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view showing an example of a typical electro-absorption modulated lasers;

FIG. 2 is a plan view showing an example of a SAG mask pattern for manufacturing an active layer of FIG. 1;

FIG. 3 is a graph showing absorption properties of the typical electro-absorption modulated lasers of FIG. 1;

FIG. 4 is a graph showing ER properties according to detuning of the typical electro-absorption modulated lasers of FIG. 1;

FIG. 5 is a cross-sectional view showing an example of an electro-absorption modulated lasers according to the inventive concept;

FIG. 6 is a plan view showing an example of a SAG mask pattern for forming an active layer of FIG. 5;

FIG. 7 is a graph showing ER properties of the electro-absorption modulated lasers of FIG. 5;

FIG. 8 shows a change in intensity of an input due to absorption inside the electro-absorption modulated lasers of FIG. 5;

FIG. 9 is a cross-sectional view showing an example of an electro-absorption modulated lasers according to the inventive concept;

FIG. 10 is a plan view showing an example of a SAG mask pattern for forming an active layer of FIG. 6;

FIG. 11 is a graph showing absorption properties of light according to an EAM wavelength of FIG. 9;

FIG. 12 is a graph showing absorption properties of long-wavelength shifted light in an EAM region of FIG. 9;

FIG. 13 is a graph showing ER properties not reflecting saturation properties of the electro-absorption modulated lasers of FIG. 9;

FIG. 14 is a graph showing ER properties reflecting saturation properties of the electro-absorption modulated lasers of FIG. 9;

FIG. 15 is a graph showing intensity of light inside an EAM due to absorption of the electro-absorption modulated lasers of FIG. 9;

FIG. 16 is a graph showing an internal light intensity distribution according to an operating voltage of the electro-absorption modulated lasers of FIG. 1;

FIG. 17 is a graph showing calculation results of an internal light intensity distribution according to a segment of an EAM region of a typical electro-absorption modulated lasers of FIG. 9;

FIG. 18 is graphs showing ER properties and an output of the typical electro-absorption modulated lasers of FIG. 1; and

FIG. 19 is graphs showing ER properties and an output of the electro-absorption modulated lasers of FIG. 9.

### DETAILED DESCRIPTION

Hereinafter, preferred embodiments of the inventive concept will be described in detail with reference to the accompanying drawings. Advantages and features of the inventive concept and methods of accomplishing the same may be understood more readily by reference to the following detailed description of exemplary embodiments and the accompanying drawings. However, the inventive concept is not limited to the embodiments described herein, and may be embodied in other forms. Rather, the embodiments introduced herein are provided to ensure that the disclosed contents may be thorough and complete, and that the spirit of the inventive concept may be sufficiently conveyed to those skilled in the art, and the inventive concept is only defined by the scope of claims. The same reference numerals refer to like elements throughout the specification.

The terms used herein are for the purpose of describing embodiments and are not intended to be limiting of the present invention. In the present specification, singular forms include plural forms unless the context clearly indicates otherwise. As used herein, the terms “comprises” and/or “comprising” are intended to be inclusive of the stated elements, operations and/or devices, and do not exclude the possibility of the presence or the addition of one or more other elements, operations, and/or devices. In addition, since the present specification is according to a preferred embodiment, reference numerals presented according to the order of description are not necessarily limited to the order.

In addition, embodiments described in the present specification will be described with reference to cross-sectional views and/or plan views which are ideal illustrations of the inventive concept. In the drawings, the thickness of films and regions are exaggerated for an effective description of technical contents. Accordingly, the shape of an exemplary drawing may be modified by manufacturing techniques and/or tolerances. Thus, the embodiments of the inventive concept are not limited to specific forms shown, but are intended to include changes in the form generated by a manufacturing process.

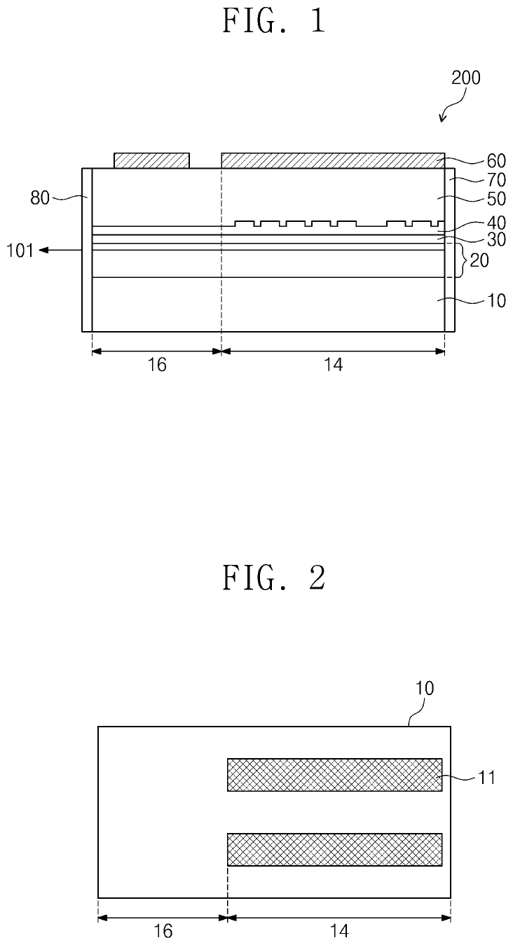

FIG. 1 shows an example of a typical electro-absorption modulated lasers 200.

Referring to FIG. 1, a typical electro-absorption modulated lasers 200 with identical-active layer may include a substrate 10, an active layer 20, an electron stop layer 30, a grating layer 40, a clad layer 50, electrodes 60, a highly reflective layer 70, and a non-reflective layer 80.

The substrate 10 may include n-InP. The substrate 10 may have a laser diode (LD) region 14 and an electro-absorption modulation (EAM) region 16. The LD region 14 may be a distributed feed-back (DFB) region that produces light 101. The EAM region 16 may be a region that modulates the light 101. The active layer 20 may be provided on the substrate 10 of the LD region 14 and the EAM region 16. For example, the active layer 20 may contain InAlGaAs MQW. The active layer 20 may be the same MQW layer. The same MQW layer may simplify the structure and process of the typical electro-absorption modulated lasers 200 by using the same MQW in the LD region 14 and the EAM region 16, rather than a typical Butt-joint method, thereby by minimizing a regrowth process. However, since the same MQW is used, there is a disadvantage in that it is difficult to independently optimize the LD region 14 and the EAM region 16.

The electron stop layer 30 may be provided on the active layer 20 in the LD region 14 and the EAM region 16. The electron stop layer 30 may improve the efficiency of the LD region 14 in which a forward bias is applied between the substrate 10 and the electrodes 60.

The grating layer 40 may be provided on the electronic stop layer 30.

The clad layer 50 may be provided on the grating layer 40.

Electrodes 60 may be provided on clad layer 50 of the LD region 14 and EAM region 16.

The typical electro-absorption modulated lasers 200 with identical-active layer is not capable of independently optimizing the LD region 14 and the EAM region 16, and may have a problem in that a long wavelength band should be used in a gain curve of the LD region 14. Therefore, it may be difficult to increase the output of the typical electro-absorption modulated lasers 200. A method for manufacturing the typical electro-absorption modulated lasers 200 is capable of solving the above-described problem by using a SAG method.

FIG. 2 shows an example of a self-align growth mask pattern (SAG) 11 when the SAG method is used to solve the above-described problem of an element having the structure of FIG. 1.

Referring to FIG. 2, the SAG mask pattern 11 may be selectively provided on the substrate 10 of the LD region 14. The SAG mask pattern 11 may have an opening that exposes a portion of the substrate 10 of the LD region 14. The opening may increase the growth thickness of the active layer 20. As a result, photoluminescence (PL) of the LD region 14 can be shifted to a long wavelength. The SAG mask pattern 11 may contain either silicon oxide (SiO₂) or silicon nitride (SiNx).

Meanwhile, if there is no SAG mask pattern 11 or if the opening is wide, there may be no change in the growth rate of the active layer 20. Consequently, the typical electro-absorption modulated lasers 200 may have properties of operating at a short wavelength. By using the above-described method, it is possible to improve the properties of the typical electro-absorption modulated lasers 200 with identical-active layer 20. However, since it is impossible to make period of the EAM region 16 and the LD region 14 different from each other, it is difficult to actively control the ER properties of the EAM region 16.

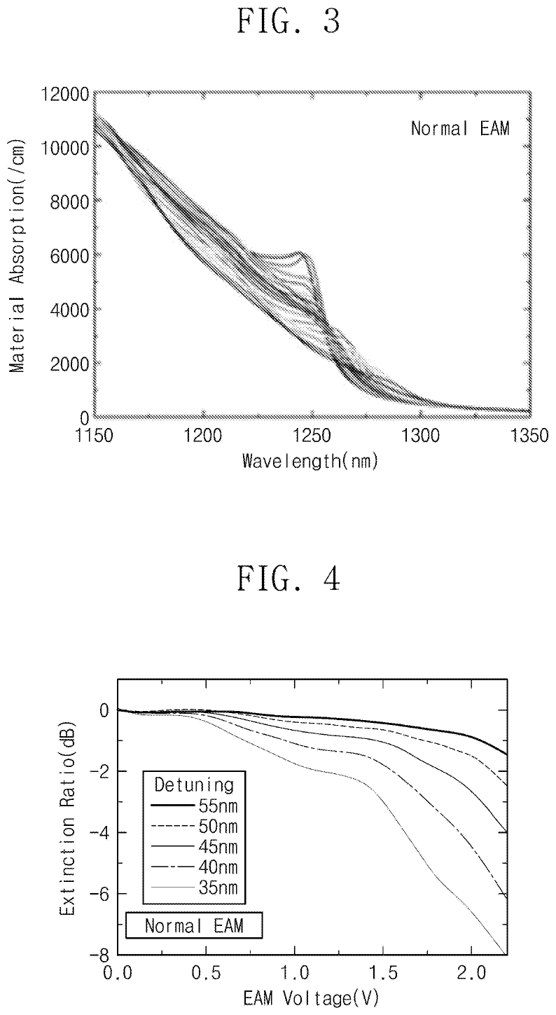

FIG. 3 shows absorption properties of the typical electro-absorption modulated lasers 200 of FIG. 1.

Referring to FIG. 3, the typical electro-absorption modulated lasers 200 may have a band edge of about 1245 nm. As a voltage applied thereto is increased, the typical electro-absorption modulated lasers 200 may have sufficient absorption properties up to about a 1280 nm band.

FIG. 4 shows ER properties according to detuning of the typical electro-absorption modulated lasers 200 of FIG. 1.

Referring to FIG. 4, the ER properties of the typical electro-absorption modulated lasers 200 may decrease according to a modulation voltage. It may be typical EAM properties in which ER properties increase as detuning decreases, but an output decreases as an absorption loss increases, and the output increases as the detuning increases, but the ER properties decrease.

Since a calculated result does not take a thermal effect and the like into consideration, it should be regarded as a dynamic extinction ratio (ER) rather than static ER ratio properties, and it is appropriate to view it as ER properties according to Vpp in an actual operating state. In a calculation process, an input of EAM is assumed to be about 15 mW. At an appropriate length available for 25 Gbps to 56 Gbps, it is shown as about 7 dB to about 8 dB (detuning about 35 nm to about 40 nm) of ER of EAM. In an actual case, the ER properties may be a controllable domain due to a confinement factor and a period change. The length and confinement factor of EAM may be constant.

The typical electro-absorption modulated lasers 200 with identical-active layer 20 may have an advantage of simplifying a process by omitting a regrowth process. However, individual optimization of light-generating properties or modulation properties may have difficulty. The typical electro-absorption modulated lasers 200 may be optimized by using the SAG method. However, it is not possible for the typical electro-absorption modulated lasers 200 to independently optimize modulation properties.

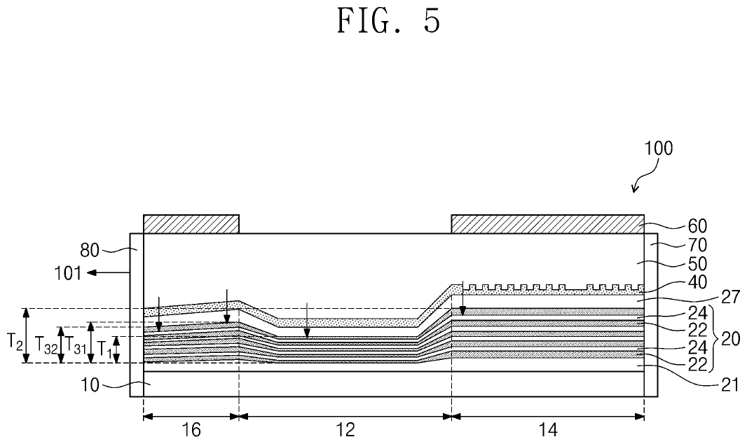

FIG. 5 shows an example of an electro-absorption modulated lasers 100 according to the inventive concept.

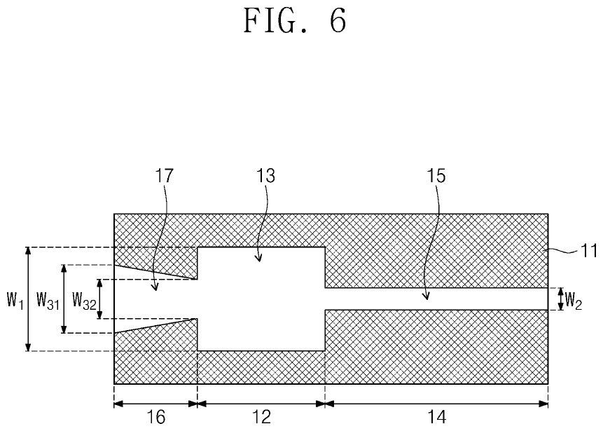

Referring to FIG. 6, the electro-absorption modulated lasers 100 of the inventive concept may include a substrate 10, an active layer 20, a grating layer 40, a clad layer 50, electrodes 60, a highly reflective layer 70, and a non-reflective layer 80.

The substrate 10 may include a passive waveguide region 12, an LD region 14, and an EAM region 16. The passive waveguide region 12 may be provided between the LD region 14 and the EAM region 16. The passive waveguide region 12 may be provided in the center of the substrate 10. The passive waveguide region 12 may be a region through which light 101 is transmitted. The LD region 14 may be provided on one side of the passive waveguide region 12. The LD region 14 may be a region in which the light 101 is generated. The EAM region 16 may be provided on the other side of the passive waveguide region 12. The EAM region 16 may be a region in which the light 101 is modulated.

A first SCH layer 21 may be provided on the substrate 10. The first SCH layer 21 may have a n-type conductivity type.

The active layer 20 may be provided on the first SCH layer 21. The active layer 20 may extend unidirectionally from the LD region 14 to the EAM region 16. The active layer 20 of the passive waveguide region 12 may have a first thickness T₁. The active layer 20 of the LD region 14 may have a second thickness T₂. The second thickness T₂ may be greater than the first thickness T₁. The active layer 20 of the EAM region 16 may have a maximum variable thickness T₃₁ to a minimum variable thickness T₃₂. The maximum variable thickness T₃₁ and the minimum variable thickness T₃₂ may be greater than the first thickness T₁, and may be less than the second thickness T₂.

According to one example, the active layer 20 may include quantum well layers 22 and barrier layers 24. Each of the quantum well layers 22 may contain InAlGaAs or InGaAsP. The barrier layers 24 may contain InAlGaAs or InGaAsP. The quantum well layers 22 and the barrier layers 24 may be alternately stacked. The quantum well layers 22 and the barrier layers 24 may be formed by the SAG method.

FIG. 6 shows an example of the SAG mask pattern 11 for forming the active layer 20 of FIG. 5.

Referring to FIG. 6, the SAG mask pattern 11 may expose a portion of the substrate 10 of the passive waveguide region 12, the LD region 14, and the EAM region 16. The SAG mask pattern 11 may include a first opening 13, a second opening 15, and a third opening 17.

The first opening 13 may be provided in the passive waveguide region 12. The first opening 13 may have a first width W1.

The second opening 15 may be provided in the LD region 14. The second opening 15 may have a second width W2. The second width W2 may be smaller than the first width W1.

The third opening 17 may be provided in the EAM region 16. The third opening 17 may have a minimum variable width W32 and a maximum variable width W31. The minimum variable width W32 and the maximum variable width W31 may be greater than the second width W2, and may be less than the first width W1. The minimum variable width W32 to the maximum variable width W31 of the SAG mask pattern 11 of the EAM region 16 may have a trapezoidal shape.

The SAG mask pattern 11 having the first width W1, the second width W2, the minimum variable width W32, and the maximum variable width W31 may adjust the thickness and composition of the quantum well layers 22 by varying the component ratio and composition ratio of Al, In, Ga, or P in the quantum well layers 22 to ultimately adjust a band gap. The thickness of the quantum well layers 22 may be inversely proportional to the width of the SAG mask pattern 11.

The SAG mask pattern 11 of the passive waveguide region 12 may form the thinnest active layer 20. The active layer 20 may have the first thickness T₁.

The SAG mask pattern 11 of the LD region 14 may form the thickest active layer 20. The active layer 20 may have the second thickness T₂.

The SAG mask pattern 11 having the minimum variable width W32 to the maximum variable width W31 may form the active layer 20 of the EAM region 16 thinner than the LD region 14 and thicker than the passive waveguide region 12. The active layer 20 of the EAM region 16 may have the maximum variable thickness T₃₁ to the minimum variable thickness T₃₂.

Although not illustrated, the SAG mask pattern 11 may be removed by a patterning process of the active layer 20.

Referring back to FIG. 5, the second SCH layer 27 may be provided on the active layer 20. The second SCH layer 27 may have a p-type conductivity type. The second SCH layer 27 may be curved within a first boundary between the passive waveguide region 12 and the LD region 14, and may be curved within a second boundary between the passive waveguide region 12 and the EAM region 16.

The grating layer 40 may be provided on the second SCH layer 27. The grating layer 40 may be curved within the first boundary between the passive waveguide region 12 and the LD region 14, and may be curved within the second boundary between the passive waveguide region 12 and the EAM region 16.

The clad layer 50 may be provided on the grating layer 40.

The electrodes 60 may be provided on the clad layer 50 of the LD region 14 and the EAM region 16.

The highly reflective layer 70 may be provided on the substrate 10 of the LD region 14, or on a sidewall of one side of the clad layer 50.

The non-reflective layer 80 may be provided on the substrate 10 of the EAM region 16, or on a side wall of the other side of the clad layer 50.

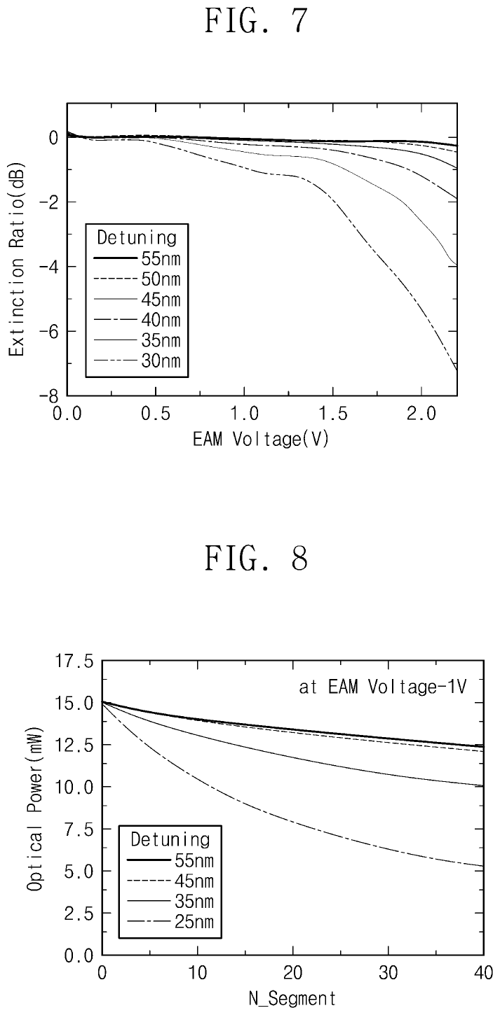

FIG. 7 shows ER properties of the electro-absorption modulated lasers 100 of FIG. 5.

Referring to FIG. 7, the ER properties may reduce depending on a voltage provided between the electrode 60 and the substrate 10 of the EAM region 16. It is assumed that an operating wavelength of an EAM output terminal is different from an input terminal by −20 nm in a calculation. Therefore, there may be an effect of increasing detuning due to an effect of decreasing an effective operating wavelength of EAM.

FIG. 8 shows a change in intensity of an input due to absorption inside the electro-absorption modulated lasers 100 of FIG. 5.

Referring to FIG. 8, as the light 101 travels through the active layer 20 of the EAM region 16, the intensity of the light may decrease due to absorption of the active layer 20 of the EAM region 16. The light 101 may have a power of about 15 mW, and may have a modulation voltage of about 1 V. The EAM region 16 was divided into about 40 segments and calculated. The light 101 in the EAM region 16 may be short-wavelength shifted in the direction of an output terminal and travel in a direction in which absorption is reduced. Consequently, simulation calculation results show that when a wavelength shift structure is used, it is possible to control not only the ER properties, but also absorption properties of the EAM region 16.

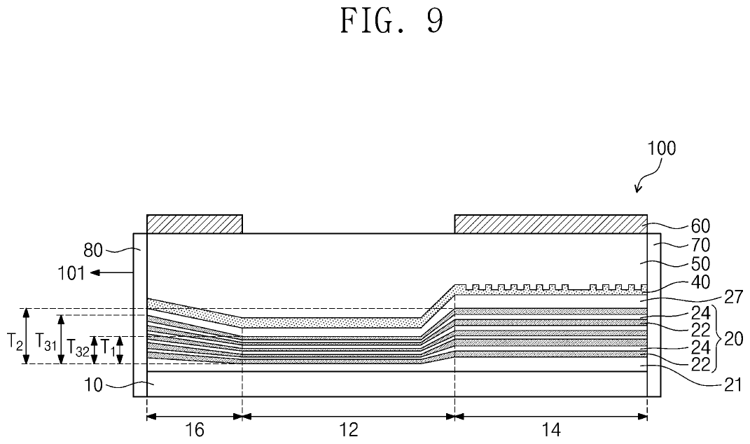

FIG. 9 shows an example of the electro-absorption modulated lasers 100 according to the inventive concept.

Referring to FIG. 9, the active layer 20 having the minimum variable thickness T₃₂ of the electro-absorption modulated lasers 100 may be linked to the passive waveguide region 12. That is, the active layer 20 of the EAM region 16 may become thinner as it gets closer to the passive waveguide region 12, and may become thicker as it moves away from the passive waveguide region 12.

The substrate 10, the first SCH layer 21, the second SCH layer 27, the grating layer 40, the clad layer 50, the electrodes 60, the highly reflective layer 70, and the non-reflective layer 80 may be configured in the same way as shown in FIG. 5.

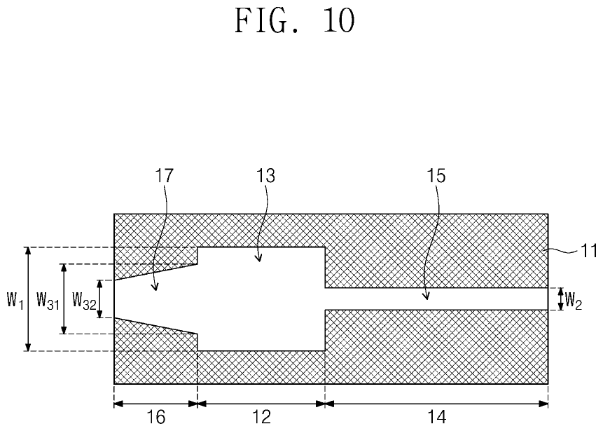

FIG. 10 shows an example of the SAG mask pattern 11 for forming the active layer 20 of FIG. 6.

Referring to FIG. 10, the maximum variable width W31 is adjacent to the passive waveguide region 12, and the minimum variable width W32 may be provided spaced away from the passive waveguide region 12. In this case, as the light 101 travels in the direction of the output terminal of the EAM, an operating wavelength of the EAM is shifted to a long wavelength.

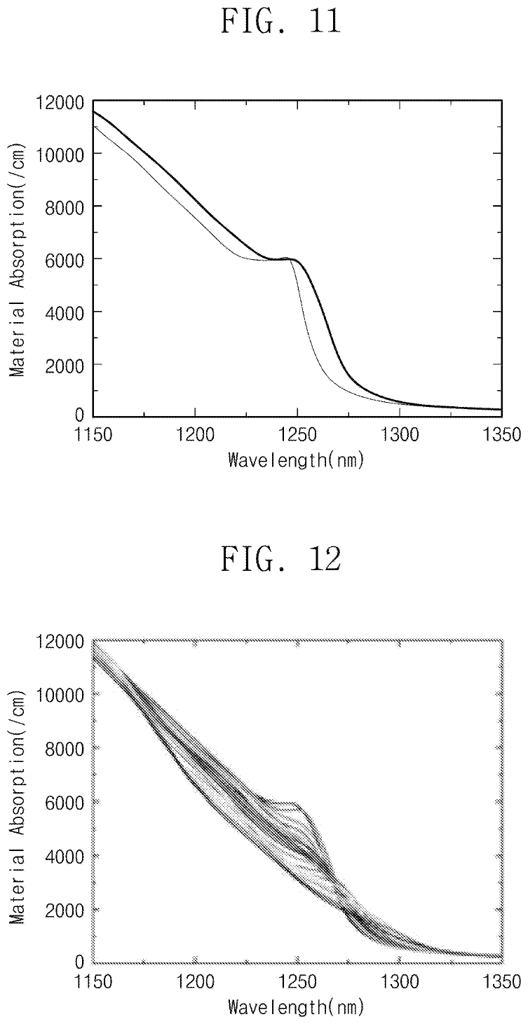

FIG. 11 shows ER properties that do not reflect absorption-saturation properties of the light 101 according to a wavelength of the EAM region 16 of FIG. 9.

Referring to FIG. 11, calculated material absorption coefficient of the EAM region 16 of the inventive concept may have a peak for the light 101 having a wavelength of about 1230 nm to about 1270 nm. While maintaining an absorption height at the peak, absorption into a long wavelength may increase. In general, absorption properties of the EAM prefers a typical structure that is clearly defined. However, although absorption properties of the entire EAM showed a wide range of absorption, absorption properties of each segment will be clearly defined.

FIG. 12 shows absorption properties of the light 101 that is long-wavelength shifted in the EAM region 16 of FIG. 9.

Referring to FIG. 12, an absorption property peak of the long-wavelength shifted light 101 may be smaller than an absorption property peak of the light 101 having a short wavelength. When considering the entire EAM as one element, it has the same absorption properties as shown in FIG. 12. Therefore, when calculating the ER in this case, it shows the same properties as if an operating wavelength of EAM is shifted to a longer wavelength, as shown in FIG. 12.

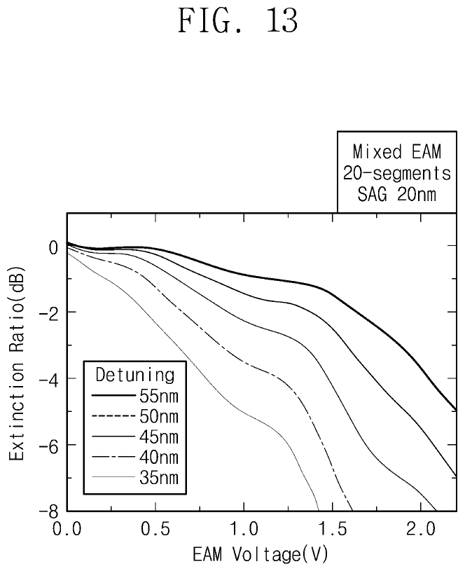

FIG. 13 shows ER properties of the electro-absorption modulated lasers 100 of FIG. 9.

Referring to FIG. 13, the ER properties of the electro-absorption modulated lasers 100 may be controlled based on a modulation voltage. EAM saturation properties were not reflected. The ER properties control may also be applied to fields that require linear ER properties of EML, such as analog applications.

It is difficult to drive the electro-absorption modulated lasers 100 in a region in which detuning is small due to structural properties. If QWs with different operating wavelengths are mixed, it is highly likely that absorption is increased and properties of a DFB LD are degraded. Therefore, if a wavelength shift section of SAG is artificially controlled and the section is used as an EAM region, the properties of the electro-absorption modulated lasers 100 may be improved, and also, it may be possible to control the modulation properties more efficiently.

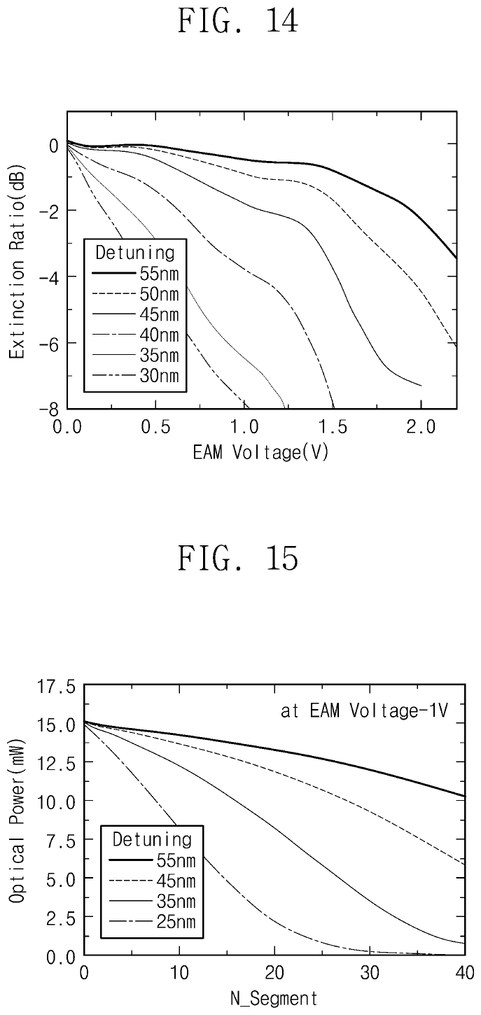

FIG. 14 shows ER properties considering saturation properties of the electro-absorption modulated lasers 100.

Referring to FIG. 14, ER properties of the electro-absorption modulated lasers 100 reflecting the saturation properties may be controlled according to a modulation voltage. The ER properties of the external modulated element 100 reflecting the saturation properties may have an absolute value different from the absolute value of ER properties not reflecting the saturation properties.

FIG. 15 shows intensity of light inside an EAM due to absorption of the electro-absorption modulated lasers 100 of FIG. 9.

Referring to FIG. 15, the electro-absorption modulated lasers 100 of the inventive concept may have a light intensity distribution that decreases very uniformly in the EAM region 16 in a detuning range of about 35 nm to about 45 nm. The modulation voltage may be about-1 V. In the case of a typical EAM, if the intensity of light is large, a large number of carriers are generated at an open terminal of EAM, and due to these carriers, there is an effect in that speed of the EAM will be reduced. However, in the case of a distributed-type EAM, effective absorption increases, but absorption may rather increase in a direction in which the intensity of light decreases. Therefore, there is a possibility in that the same absorption properties are shown while reducing saturation properties of an EAM input terminal.

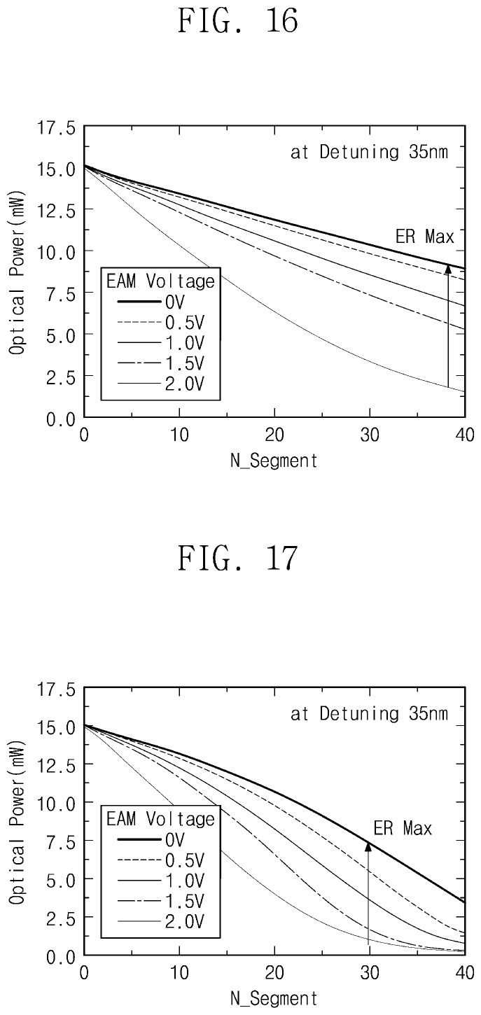

FIG. 16 shows an internal light intensity distribution according to an operating voltage of the typical electro-absorption modulated lasers 200 of FIG. 1.

Referring to FIG. 16, in the typical electro-absorption modulated lasers 200 of FIG. 1, it is possible to have a non-uniform absorption distribution in the EAM region 16 in a detuning range of about 35 nm. A typical EAM may have properties in that as the length increases, ER properties increase, and at the same time, an output continuously decreases.

FIG. 17 shows calculation results of an internal light intensity distribution according to a segment of the EAM region 16 of the typical electro-absorption modulated lasers 200 of FIG. 9.

Referring to FIG. 17, the modulation element 100 of the inventive concept may have light intensity that decreases in proportion to a modulation voltage since absorption in the EAM region 16 increases. Nevertheless, in the case of a distributed type, the point at which the maximum ER properties are shown is a point of about 75% of the EAM length, and it can be confirmed that the output at this time is maintained at a high level. A wavelength shift at a 75% point of the total is about 15 nm. Therefore, if a wavelength shift of about 15 nm is implemented, the same ER may be secured in a shorter length compared to a typical EAM structure. The light 101 in the distributed-type EAM has been subjected to a wavelength shift by about +20 nm to a long wavelength.

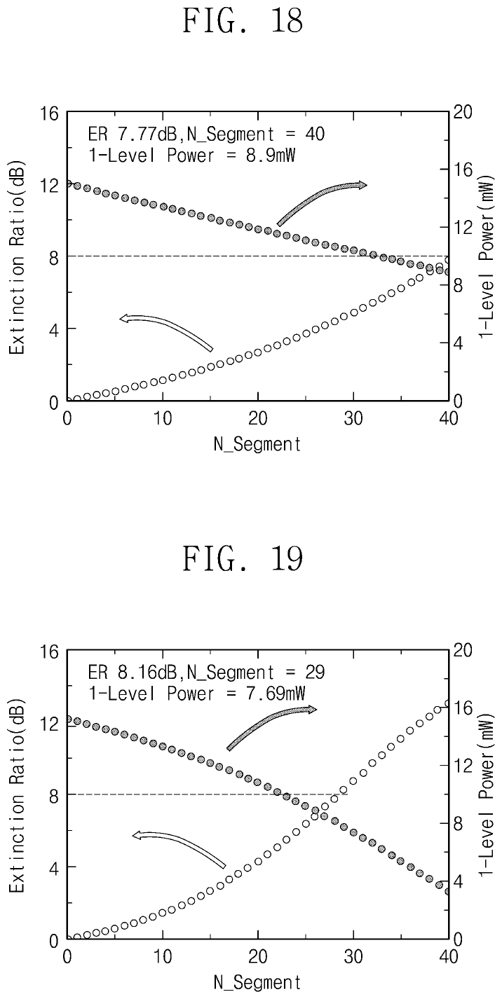

FIG. 18 shows ER properties and an output of the typical electro-absorption modulated lasers 200 of FIG. 1.

Referring to FIG. 18, the typical electro-absorption modulated lasers 200 may have a modulation rate inversely proportional to the length of the EAM region 16. As the length of EAM region 16 decreases, the modulation rate may increase. As the length of the EAM region 16 decreases, the ER properties may decrease, and the output of the entire element may increase.

FIG. 19 shows ER properties and an output of the electro-absorption modulated lasers 100 of FIG. 9.

Referring to FIG. 19, the length of the EAM region 16 that may secure ER properties of about 8 dB may be reduced by about 75%. The output of the electro-absorption modulated lasers 100 of the inventive concept is about 7.69 mW, and there is little difference compared to that of the typical electro-absorption modulated lasers 200 calculated earlier. The electro-absorption modulated lasers 100 of the inventive concept may improve the speed of an EAM, and may maintain properties of a DFB LD. Consequently, the electro-absorption modulated lasers 100 of the inventive concept may significantly improve properties of the electro-absorption modulated lasers 100.

As described above, an electro-absorption modulated lasers with identical-active layer according to an embodiment of the inventive concept may acquire linear ER properties by using active layers extending from an LD region to an EAM region on both sides of a passive waveguide region and having different thicknesses.

Although the embodiments of the present invention have been described with reference to the accompanying drawing, those skilled in the art will understand that the present invention can be implemented in other specific forms without changing the technical spirit or essential features thereof. Therefore, the embodiments described above should be understood as illustrative in all respects and not restrictive.

What is claimed is:

1. An electro-absorption modulated lasers with identical-active layer, the lasers comprising:
a substrate having a passive waveguide region, an LD region on one side of the passive waveguide region, and an EAM region on another side of the passive waveguide region;
an active layer provided on the substrate and extending from the LD region to the EAM region;
a grating layer provided on the active layer;
a clad layer provided on the grating layer; and
electrodes provided in the LD region and the EAM region of the clad layer,
wherein the active layer has:
a first thickness in the passive waveguide region;
a second thickness, which is greater than the first thickness, in the LD region; and
a minimum variable thickness and a maximum variable thickness, which are greater than the first thickness and less than the second thickness, in the EAM region.

2. The electro-absorption modulated lasers of claim 1, wherein the active layer having the maximum variable thickness is provided adjacent to the passive waveguide region.

3. The electro-absorption modulated lasers of claim 1, wherein the active layer having the minimum variable thickness is provided adjacent to the passive waveguide region, and the minimum variable thickness is the same as the first thickness.

4. The electro-absorption modulated lasers of claim 1, further comprising:
a first SCH layer between the substrate and the active layer; and
a second SCH sublayer between the active layer and the grating layer.

5. The electro-absorption modulated lasers of claim 4, wherein the active layer is curved between the passive waveguide region and the LD region, and is curved between the passive waveguide region and the EAM region.

6. The electro-absorption modulated lasers of claim 1, wherein the grating layer extends from the LD region to the EAM region.

7. The electro-absorption modulated lasers of claim 1, wherein the grating layer is curved between the passive waveguide region and the LD region, and is curved between the passive waveguide region and the EAM region.

8. The electro-absorption modulated lasers of claim 1, wherein the active layer is formed by a SAG method using a SAG mask pattern as a deposition mask.

9. The electro-absorption modulated lasers of claim 8, wherein the SAG mask pattern comprises:
a first opening having a first width in the passive waveguide region;
a second opening having a second width, which is narrower than the first width, in the LD viewing region; and
a third opening having a maximum variable width and a minimum variable width, which are narrower than the first width and wider than the second width, in the EAM region.

10. The electro-absorption modulated lasers of claim 9, wherein the maximum variable width is the same as the second width.

11. An electro-absorption modulated lasers with identical-active layer, the lasers comprising:
a substrate having a passive waveguide region, an LD region on one side of the passive waveguide region, and an EAM region on another side of the passive waveguide region;
an active layer provided on the substrate and thinner than the EAM region in the passive waveguide region and thicker than the EAM region in the LD region;
a grating layer provided on the active layer;
a clad layer provided on the grating layer; and
electrodes provided in the LD region and the EAM region of the clad layer.

12. The electro-absorption modulated lasers of claim 11, wherein the active layer extends from the LD region to the EAM region.

13. The electro-absorption modulated lasers of claim 11, wherein the active layer is formed by a SAG method using a SAG mask pattern as a deposition mask.

14. The electro-absorption modulated lasers of claim 13, wherein the SAG mask pattern comprises:
a first opening having a first width in the passive waveguide region;
a second opening having a second width in the LD region; and
a third opening having a variable width in the EAM region.

15. The electro-absorption modulated lasers of claim 14, wherein the variable width is narrower than the first width and wider than the second width.

16. An electro-absorption modulated lasers with identical-active layer, the lasers comprising:
a substrate having a passive waveguide region, a laser diode region on one side of the passive waveguide region, and a modulation region on another side of the passive waveguide region;
an active layer provided on the substrate and extending from the laser diode region to the modulation region;
a grating layer provided on the active layer;
a clad layer provided on the grating layer; and
electrodes provided in the laser diode region and the passive waveguide region of the clad layer,
wherein the modulation region of the active layer is thicker than the passive waveguide region and thinner than the laser diode region.

17. The electro-absorption modulated lasers of claim 16, wherein the active layer has:
a first thickness in the passive waveguide region;
a second thickness, which is greater than the first thickness, in the laser diode region; and
a third thickness, which is greater than the first thickness and less than the second thickness, in the modulation region.

18. The electro-absorption modulated lasers of claim 17, wherein the third thickness comprises a maximum variable thickness and a minimum variable thickness.

19. The electro-absorption modulated lasers of claim 18, wherein the active layer having the maximum variable thickness is provided adjacent to the passive waveguide region.

20. The electro-absorption modulated lasers of claim 18, wherein the minimum variable thickness is the same as the first thickness.
